(19) United States
(12) Patent Application Publication
(10) Pub. No.: US 2026/0282253 A1
(43) Pub. Date: Sep. 17, 2026

(54) AUTOMATION SYSTEM AND CHASSIS THEREOF

(71) Applicant: Wistron Corp., New Taipei City (TW)

(72) Inventors: Yong Qing ZHONG, New Taipei City (TW); Longhua WU, New Taipei City (TW); Yisheng CHEN, New Taipei City (TW); Chihhsiang CHU, New Taipei City (TW)

(21) Appl. No.: 19/221,973

(22) Filed: May 29, 2025

(30) Foreign Application Priority Data
Mar. 11, 2025 (CN) 202510288878.8

(51) Int. Cl. H05K 5/02

(52) U.S. Cl. CPC H05K 5/0221; H05K 5/023

(57) ABSTRACT

A chassis is provided. The chassis includes a main body, a bracket, a handle, and a locking mechanism. The bracket is configured to slide relative to the main body. The handle is rotatably disposed on the bracket. The handle includes a hook. The locking mechanism is disposed on the main body. The locking mechanism is switchable between a locked state and an unlocked state. The hook is configured to engage with the locking mechanism. The locking mechanism includes a rotating rod pivotally connected to the main body. The handle is configured to rotate between a first handle position and a second handle position relative to the bracket, so that when the handle is in the first handle position, the hook engages with the locking mechanism, and when the handle is in the second handle position, the hook disengages from the locking mechanism.

### CROSS REFERENCE TO RELATED APPLICATIONS

This Application claims priority of China Patent Application No. 202510288878.8, filed on Mar. 11, 2025, the entirety of which is incorporated by reference herein.

### BACKGROUND OF THE INVENTION

### Field of the Invention

The present invention relates to a chassis, and, in particular, it relates to a chassis that can be configured in an automation system.

### Description of the Related Art

To realize the concept of a fully automated factory, there is a growing demand for automation in areas such as hardware testing and disassembly. Using conventional technology, electronic components (e.g., graphics cards, hard drives, etc.) on electronic devices such as servers typically require manual disassembly before they can be tested. This process is inefficient, labor-intensive, and time-consuming. As such, conventional chassis designs are gradually falling short of current market demands.

### BRIEF SUMMARY OF THE INVENTION

An embodiment of the invention provides a chassis. The chassis includes a main body, a bracket, a handle, and a locking mechanism. The bracket is configured to slide relative to the main body. The handle is rotatably disposed on the bracket, wherein the handle includes a hook. The locking mechanism is disposed on the main body, wherein the locking mechanism is switchable between a locked state and an unlocked state, the hook is configured to engage with the locking mechanism, and the locking mechanism includes a rotating rod pivotally connected to the main body. The handle is configured to rotate between a first handle position and a second handle position relative to the bracket, so that when the handle is in the first handle position, the hook engages with the locking mechanism, and when the handle is in the second handle position, the hook disengages from the locking mechanism.

In one embodiment, the locking mechanism is switchable between the locked state and the unlocked state by rotating the rotating rod, the rotating rod includes a latch portion, and when the locking mechanism is in the locked state, the hook is configured to engage the latch portion

In one embodiment, the locking mechanism further includes a lever, one end of the lever is rotatably connected to the connecting end of the rotating rod, so that when an external force pushes the lever, the lever rotates the rotating rod to switch the locking mechanism from the locked state to the unlocked state.

In one embodiment, the latch portion is located between the connecting end and the pivot portion of the rotating rod, and the rotating rod is pivotally connected to the main body through the pivot portion.

In one embodiment, the lever is pivotally connected to the main body, and a pushing portion is formed on the other end of the lever .

In one embodiment, the locking mechanism further includes an elastic element, and when the locking mechanism is in the unlocked state, the elastic element forces the rotating rod to switch the locking mechanism to the locked state.

In one embodiment, the elastic element is a torsion spring, one end of the torsion spring is connected to the main body, and the other end of the torsion spring is connected to the rotating rod.

In one embodiment, the rotating rod includes a guiding slot, the main body includes a guiding post, and the guiding post is located in the guiding slot.

In one embodiment, the guiding slot is formed in the latch portion.

In one embodiment, the latch portion includes a first abutting surface and a second abutting surface, the first abutting surface is higher than the second abutting surface, and the hook is configured to engage with either the first abutting surface or the second abutting surface.

In one embodiment, the latch portion includes a guiding slope, and during the insertion of the bracket into the main body, the handle is in the first handle position, and the hook slides along the guiding slope and pushes up the latch portion.

In one embodiment, the latch portion includes a stop surface higher than the guiding slope, and the handle includes a pushing tip, and during a rotation of the handle from the first handle position to the second handle position, the pushing tip pushes against the stop surface.

In one embodiment, the handle includes a first handle component and a second handle component, the first handle component is pivotally connected to the second handle component, the hook is formed on the first handle component, and the pushing tip is formed on the second handle component.

In one embodiment, the handle further includes a backstop mechanism disposed on the second handle component, the first handle component includes a toothed portion, and the backstop mechanism engages the toothed portion to restrict relative movement between the pushing tip and the hook.

In one embodiment, the handle further includes a first elastic sheet and a second elastic sheet, the first elastic sheet is connected to the first handle component and the second handle component to exert a force on the first handle component.

In one embodiment, the second elastic sheet is connected to the backstop mechanism and the second handle component to exert a force on the backstop mechanism.

In one embodiment, the chassis further includes a gripped member, wherein the gripped member is connected to the bracket and protrudes from the bracket.

In another embodiment, an automation system is provided. The automation system includes a chassis and a robotic apparatus. The chassis includes a main body, a bracket, a handle, a locking mechanism and a gripped member. The bracket is configured to slide relative to the main body. The handle is rotatably disposed on the bracket, wherein the handle includes a hook. The locking mechanism is disposed on the main body, wherein the locking mechanism is switchable between a locked state and an unlocked state, the hook is configured to engage the locking mechanism, and the locking mechanism includes a rotating rod pivotally connected to the main body. The gripped member is connected to the bracket. The robotic apparatus includes a gripper, wherein the gripper is configured to grasp the gripped member to move the bracket.

In one embodiment, the locking mechanism is switchable between the locked state and the unlocked state by rotating the rotating rod, the rotating rod includes a latch portion, and when the locking mechanism is in the locked state, the hook engages the latch portion, the locking mechanism further includes a lever with one end rotatably connected to the connecting end of the rotating rod, the robotic apparatus further includes a pushing component, wherein when the pushing component pushes the lever, the lever rotates the rotating rod to switch the locking mechanism from the locked state to the unlocked state.

In one embodiment, the latch portion is located between the connecting end and the pivot portion of the rotating rod, and the rotating rod is pivotally connected to the main body via the pivot portion.

Utilizing the automation system and chassis of the embodiment of the invention, a robotic apparatus can use a gripper to grip the gripped member and move the bracket. As a result, electronic components (such as graphics cards, hard drives, etc.) can be automatically removed and tested. This greatly enhances efficiency, reduces labor, and saves time, meeting the growing market trend toward automation. Furthermore, by using the pushing member to actuate the lever, the locking mechanism can switch from the locked state to the unlocked state, enabling automated unlocking functionality.

### BRIEF DESCRIPTION OF THE DRAWINGS

FIG. 1 is an assembled view of a chassis of an embodiment of the invention;

FIG. 2 shows the details of a locking mechanism of the embodiment of the invention;

FIG. 3 shows a bracket and a handle of the embodiment of the invention;

FIG. 4A shows the locking mechanism of the embodiment of the invention in a locked state;

FIG. 4B shows the locking mechanism of the embodiment of the invention in an unlocked state;

FIG. 5A shows the handle of the embodiment of the invention in a first handle position;

FIG. 5B shows the handle of the embodiment of the invention in a second handle position;

FIGS. 6A, 6B and 6C show the hook engaging with the latch portion of the embodiment of the invention;

FIG. 7 shows the hook pushing the locking mechanism of the embodiment of the invention;

FIG. 8A is an exploded view of the handle of another embodiment of the invention;

FIG. 8B is an assembled view of the handle of the embodiment shown in FIG. 8A; and

FIG. 9 shows an automation system of an embodiment of the invention.

### DETAILED DESCRIPTION OF THE INVENTION

The following description is made for the purpose of illustrating the general principles of the invention and should not be taken in a limiting sense. The scope of the invention is best determined by reference to the appended claims.

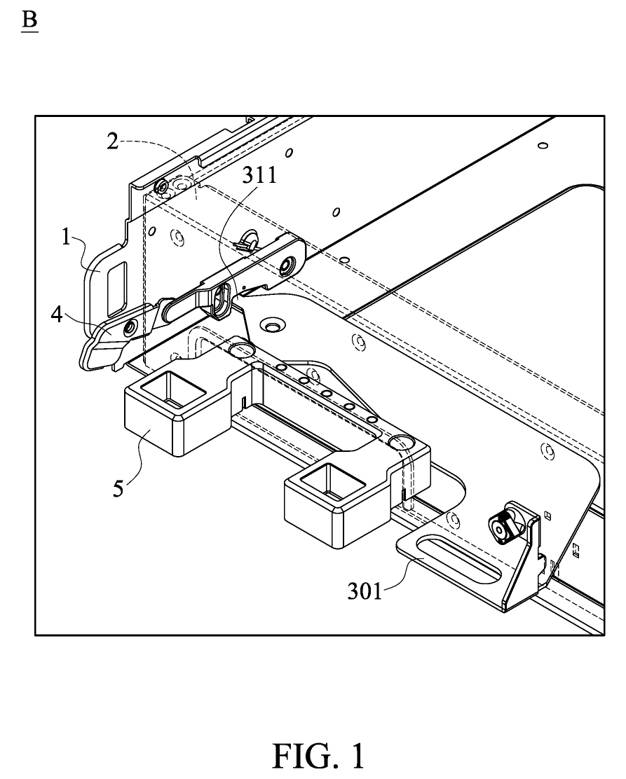

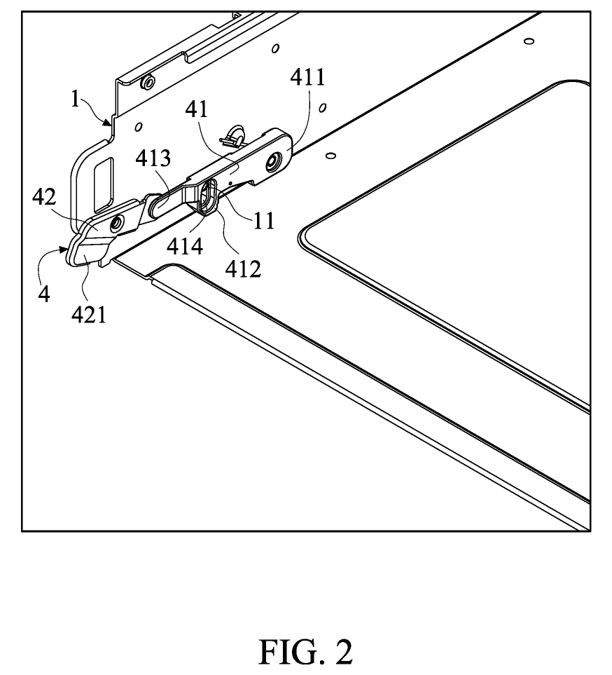

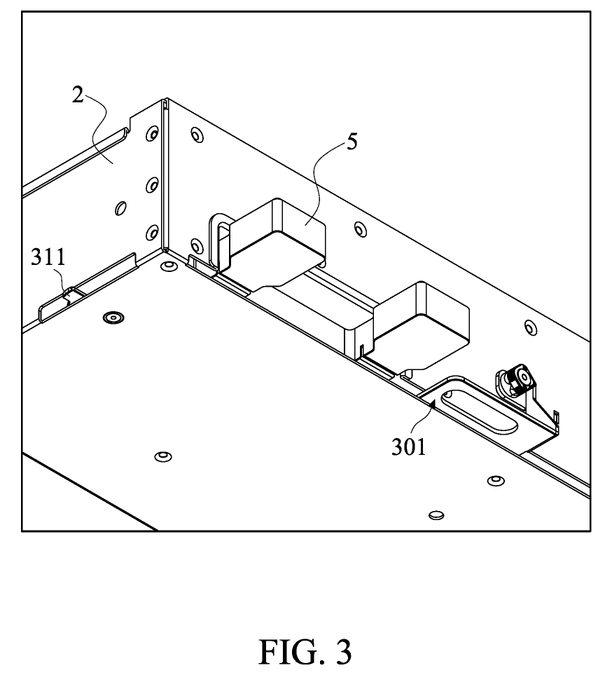

FIG. 1 is an assembled view of a chassis of an embodiment of the invention. FIG. 2 shows the details of a locking mechanism of the embodiment of the invention. FIG. 3 shows a bracket and a handle of the embodiment of the invention. With reference to FIGS. 1, 2 and 3, in one embodiment, the chassis B of the embodiment of the invention includes a main body 1, a bracket 2, a handle 301 and a locking mechanism 4. The bracket 2 is configured to slide relative to the main body 1. The handle 301 is rotatably disposed on the bracket 2 and includes a hook 311. The locking mechanism 4 is disposed on the main body 1.

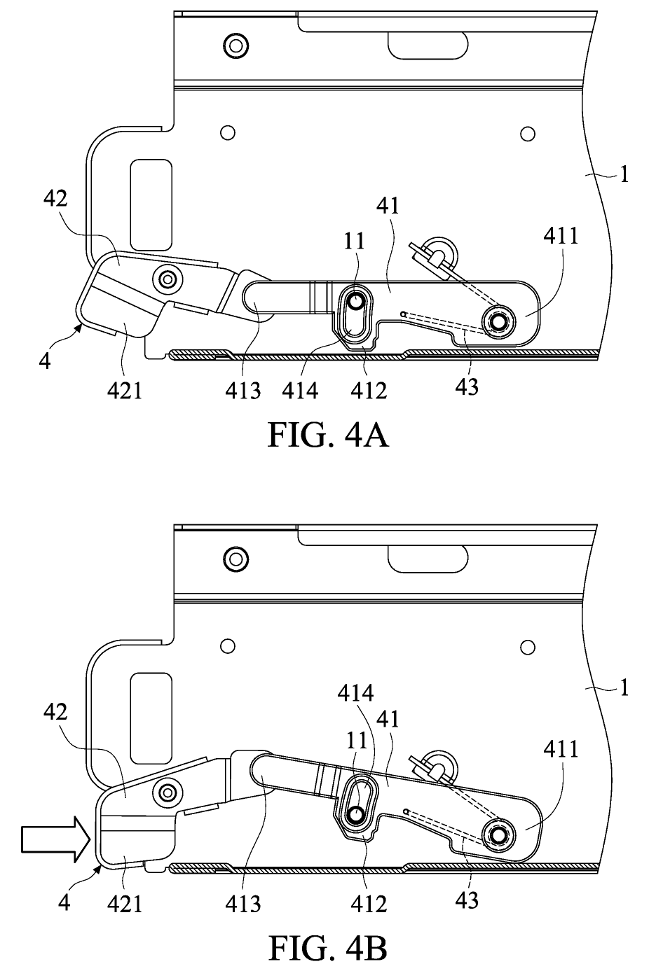

FIG. 4A shows the locking mechanism of the embodiment of the invention in a locked state. FIG. 4B shows the locking mechanism of the embodiment of the invention in an unlocked state. With reference to FIGS. 1, 4A, and 4B, the locking mechanism 4 is switchable between a locked state (FIG. 4A) and an unlocked state (FIG. 4B). The hook 311 is configured to engage with the locking mechanism 4.

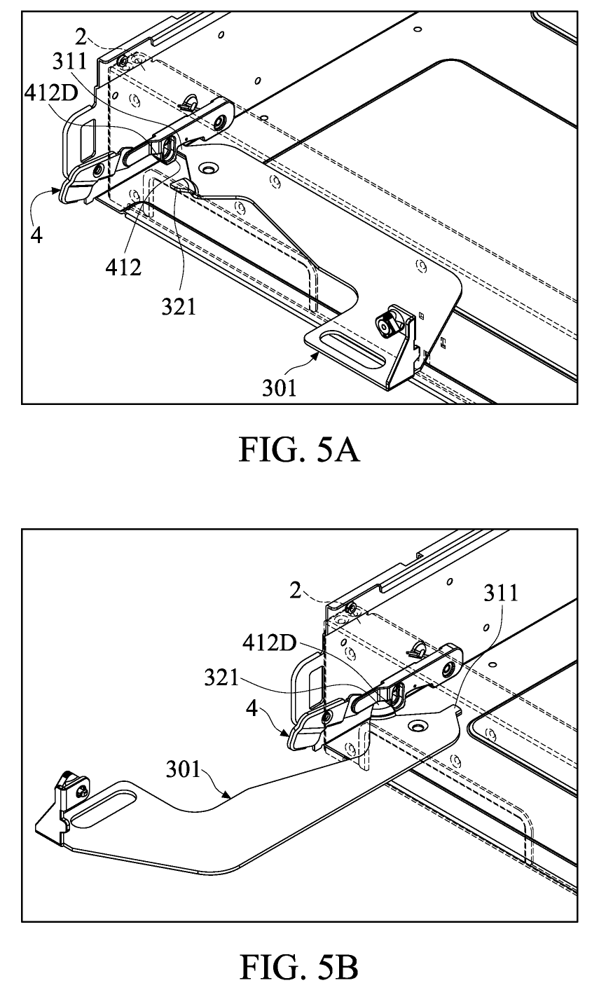

FIG. 5A shows the handle of the embodiment of the invention in a first handle position. FIG. 5B shows the handle of the embodiment of the invention in a second handle position. With reference to FIGS. 5A and 5B, in one embodiment, the handle 301 is rotatable relative to the bracket 2 between a first handle position (FIG. 5A) and a second handle position (FIG. 5B). When the handle 301 is in the first handle position (FIG. 5A), the hook 311 engages with the locking mechanism 4. When the handle 301 is in the second handle position (FIG. 5B), the hook 311 disengages from the locking mechanism 4.

With reference to FIGS. 2, 4A, and 4B, in one embodiment, the locking mechanism 4 includes a rotating rod 41. A pivot portion 411 of the rotating rod 41 is pivotally connected to the main body 1. By rotating the rotating rod 41, the locking mechanism 4 can be switched between the locked state (FIG. 4A) and the unlocked state (FIG. 4B).

With reference to FIGS. 2, 4A, 4B, and 5A, in one embodiment, the rotating rod 41 includes a latch portion 412. When the locking mechanism is in the locked state, the hook 311 is configured to engage with the latch portion 412.

With reference to FIGS. 2, 4A, and 4B, in one embodiment, the locking mechanism 4 further includes a lever 42. One end of the lever 42 is rotatably connected to the connecting end 413 of the rotating rod 41. When an external force pushes the lever 42, the lever 42 rotates the rotating rod 41, thereby switching the locking mechanism 4 from the locked state (FIG. 4A) to the unlocked state (FIG. 4B).

With reference to FIGS. 2, 4A, and 4B, in one embodiment, the latch portion 412 is located between the connecting end 413 and the pivot portion 411.

With reference to FIGS. 2, 4A, and 4B, in one embodiment, the lever 42 is pivotally connected to the main body 1. A pushing portion 421 is formed on the other end of the lever 42.

With reference to FIGS. 4A and 4B, in one embodiment, the locking mechanism 4 further includes an elastic element 43. When the locking mechanism 4 is in the unlocked state, the elastic element 43 forces the rotating rod 41, causing the locking mechanism 4 to return to the locked state, thereby enabling automatic locking.

With reference to FIGS. 4A and 4B, in one embodiment, the elastic element 43 is a torsion spring. One end of the elastic element 43 is connected to the main body 1, and the other end of the elastic element 43 is connected to the rotating rod 41.

With reference to FIGS. 2, 4A, and 4B, in one embodiment, the rotating rod 41 includes a guiding slot 414, and the main body 1 includes a guiding post 11. The guiding post 11 extends into the guiding slot 414 to provide limiting and guiding functionality.

With reference to FIGS. 2, 4A, and 4B, in one embodiment, the guiding slot 414 is formed on the latch portion 412.

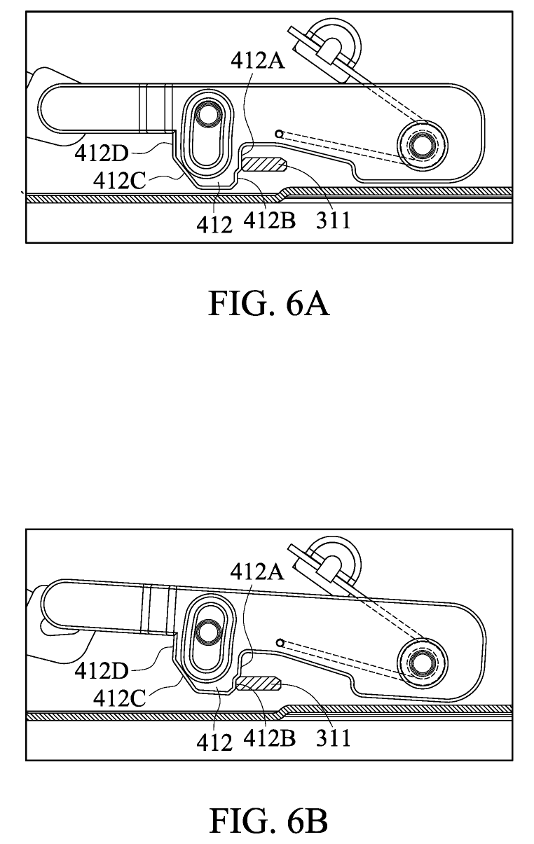

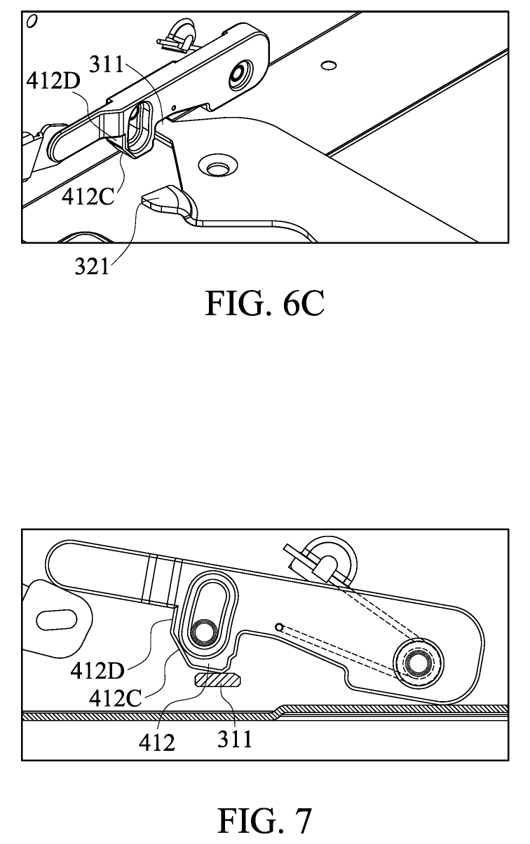

FIGS. 6A, 6B and 6C show the hook engaging with the latch portion of the embodiment of the invention. With reference to FIGS. 6A, 6B and 6C, in one embodiment, the latch portion 412 includes a first abutting surface 412A and a second abutting surface 412B. The first abutting surface 412A is higher than the second abutting surface 412B. The hook 311 is configured to engage with either the first abutting surface 412A or the second abutting surface 412B.

FIG. 7 shows the hook pushing the locking mechanism of the embodiment of the invention. With reference to FIGS. 6C and 7, in one embodiment, the latch portion 412 includes a guiding slope 412C. During the process of inserting the bracket into the main body, the handle remains in the first handle position, and the hook 311 slides along the guiding slope 412C and pushes the latch portion 412 upward.

With reference to FIGS. 6C and 7, in one embodiment, the latch portion 412 includes a stop surface 412D, which is higher than the guiding slope 412C. The handle includes a pushing tip 321. During the rotation of the handle from the first handle position to the second handle position, the pushing tip 321 presses against the stop surface 412D.

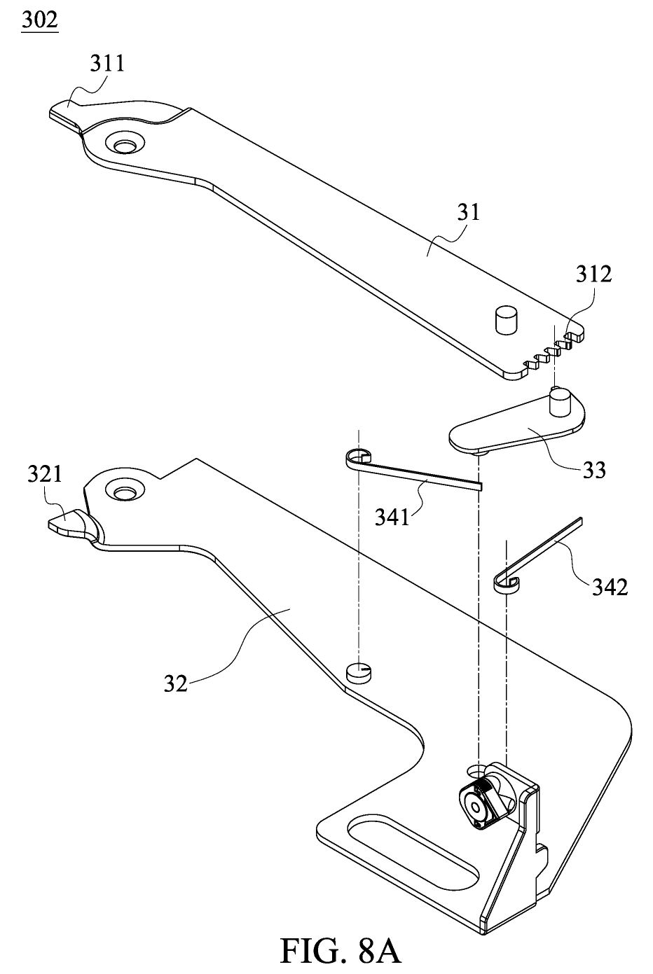

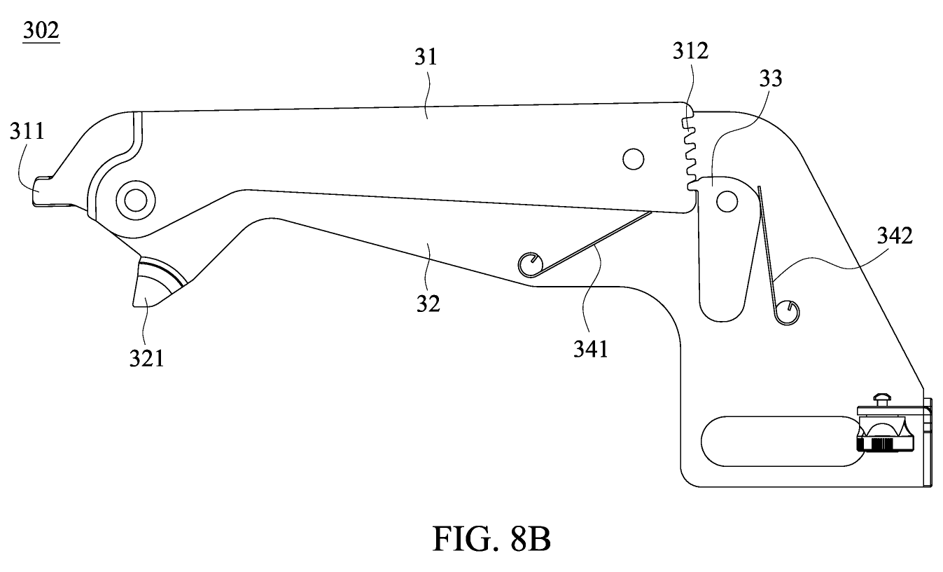

FIG. 8A is an exploded view of the handle of another embodiment of the invention. FIG. 8B is an assembled view of the handle of the embodiment shown in FIG. 8A. With reference to FIGS. 8A and 8B, in one embodiment, the handle 302 includes a first handle component 31 and a second handle component 32. The first handle component 31 is pivotally connected to the second handle component 32. The hook 311 is formed on the first handle component 31, and the pushing tip 312 is formed on the second handle component 32.

With reference to FIGS. 8A and 8B, in one embodiment, the handle 302 further includes a backstop mechanism 33. The backstop mechanism 33 is disposed on the second handle component 32. The first handle component 31 includes a toothed portion 312. The toothed portion 312 is engaged by the backstop mechanism 33 to restrict the relative distance between the pushing tip 321 and the hook 311.

With reference to FIGS. 8A and 8B, in one embodiment, the handle 302 further includes a first elastic sheet 341 and a second elastic sheet 342. The first elastic sheet 341 connects the first handle component 31 and the second handle component 32 to apply force to the first handle component 31. The second elastic sheet 342 connects the backstop mechanism 33 and the second handle component 32 to apply force to the backstop mechanism 33.

With reference to FIGS. 1 and 3, in one embodiment, the chassis further includes a gripped member 5. The gripped member 5 is connected to the bracket 2.

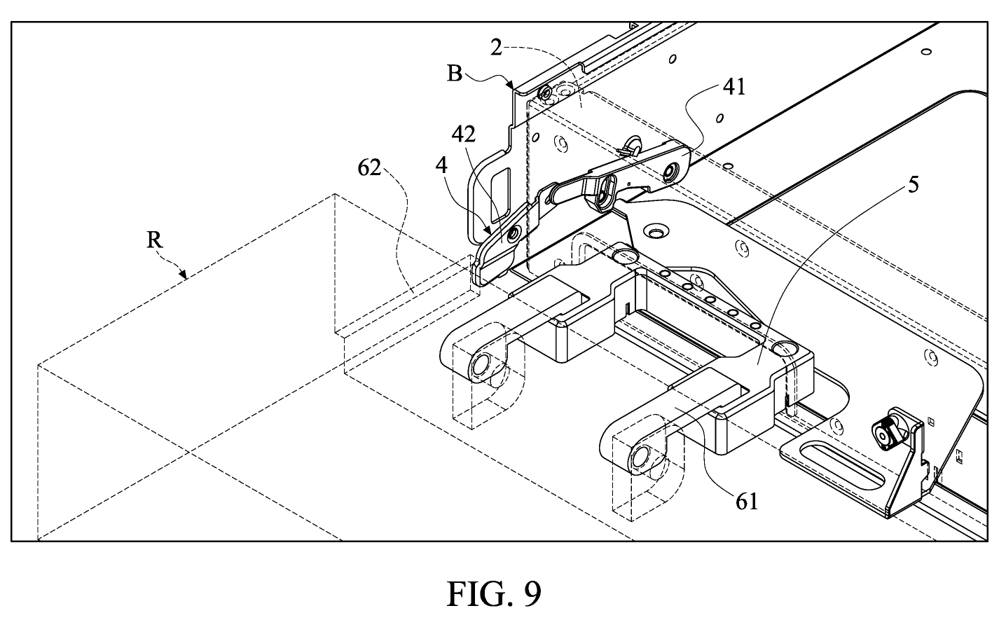

FIG. 9 shows an automation system of an embodiment of the invention. With reference to FIG. 9, the automation system includes the chassis B and a robotic apparatus R. The robotic apparatus R includes a gripper 61. The gripper 61 is configured to grip the gripped member 5 to move the bracket 2.

With reference to FIG. 9, in one embodiment, the robotic apparatus R further includes a pushing member 62. When the pushing member 62 actuates the lever 42, the lever 42 rotates the rotating rod 41, switching the locking mechanism 4 from the locked state to the unlocked state.

The chassis according to the embodiment of the invention can be utilized to manually or automatically install or remove the bracket. With reference to FIGS. 5A, 5B, and 6A, by manually rotating the handle 301, the bracket 2 can be manually locked (FIG. 5A) or unlocked/removed (FIG. 5B). When the bracket 2 is manually locked, the hook 311 engages with the first abutting surface 412A. With reference to FIGS. 6B, 7, and 9, by automatically moving the bracket 2 (while the handle 301 remains in the first handle position), the bracket 2 can be automatically locked (FIG. 6B) or unlocked/removed (FIG. 9). When the bracket 2 is automatically locked, the hook 311 engages with the second abutting surface 412B.

Utilizing the automation system and chassis of the embodiment of the invention, a robotic apparatus can use a gripper to grip the gripped member and move the bracket. As a result, electronic components (such as graphics cards, hard drives, etc.) can be automatically removed and tested. This greatly enhances efficiency, reduces labor, and saves time, meeting the growing market trend toward automation. Furthermore, by using the pushing member to actuate the lever, the locking mechanism can switch from the locked state to the unlocked state, enabling automated unlocking functionality.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chassis, comprising:
a main body;
a bracket, configured to slide relative to the main body;
a handle, rotatably disposed on the bracket, wherein the handle comprises a hook; and
a locking mechanism, disposed on the main body, wherein the locking mechanism has a locked state and an unlocked state, the hook is configured to engage with the locking mechanism, and the locking mechanism comprises a rotating rod pivotally connected to the main body,
wherein the handle is configured to rotate between a first handle position and a second handle position relative to the bracket, so that when the handle is in the first handle position, the hook engages with the locking mechanism, and when the handle is in the second handle position, the hook disengages from the locking mechanism.

2. The chassis as claimed in claim 1, wherein the locking mechanism is switchable between the locked state and the unlocked state by rotating the rotating rod, the rotating rod comprises a latch portion, and when the locking mechanism is in the locked state, the hook is configured to engage the latch portion.

3. The chassis as claimed in claim 2, wherein the locking mechanism further comprises a lever, one end of the lever is rotatably connected to a connecting end of the rotating rod, so that when an external force pushes the lever, the lever rotates the rotating rod to switch the locking mechanism from the locked state to the unlocked state.

4. The chassis as claimed in claim 3, wherein the latch portion is located between the connecting end and a pivot portion of the rotating rod, and the rotating rod is pivotally connected to the main body through the pivot portion.

5. The chassis as claimed in claim 4, wherein the lever is pivotally connected to the main body, and a pushing portion is formed on the other end of the lever.

6. The chassis as claimed in claim 5, wherein the locking mechanism further comprises an elastic element, and when the locking mechanism is in the unlocked state, the elastic element forces the rotating rod to switch the locking mechanism to the locked state.

7. The chassis as claimed in claim 6, wherein the elastic element is a torsion spring, one end of the torsion spring is connected to the main body, and the other end of the torsion spring is connected to the rotating rod.

8. The chassis as claimed in claim 6, wherein the rotating rod comprises a guiding slot, the main body comprises a guiding post, and the guiding post is located in the guiding slot.

9. The chassis as claimed in claim 8, wherein the guiding slot is formed in the latch portion.

10. The chassis as claimed in claim 8, wherein the latch portion comprises a first abutting surface and a second abutting surface, the first abutting surface is higher than the second abutting surface, and the hook is configured to engage with either the first abutting surface or the second abutting surface.

11. The chassis as claimed in claim 8, wherein the latch portion comprises a guiding slope, and during the process of the bracket inserting into the main body, the handle is in the first handle position, and the hook slides along the guiding slope and pushes up the latch portion.

12. The chassis as claimed in claim 11, wherein the latch portion comprises a stop surface higher than the guiding slope, and the handle comprises a pushing tip, and during a rotation of the handle from the first handle position to the second handle position, the pushing tip pushes against the stop surface.

13. The chassis as claimed in claim 12, wherein the handle comprises a first handle component and a second handle component, the first handle component is pivotally connected to the second handle component, the hook is formed on the first handle component, and the pushing tip is formed on the second handle component.

14. The chassis as claimed in claim 13, wherein the handle further comprises a backstop mechanism disposed on the second handle component, the first handle component comprises a toothed portion, and the backstop mechanism engages the toothed portion to restrict relative movement between the pushing tip and the hook.

15. The chassis as claimed in claim 14, wherein the handle further comprises a first elastic sheet and a second elastic sheet, the first elastic sheet is connected to the first handle component and the second handle component.

16. The chassis as claimed in claim 15, wherein the second elastic sheet is connected to the backstop mechanism and the second handle component to exert a force on the backstop mechanism.

17. The chassis as claimed in claim 1, further comprising a gripped member, wherein the gripped member is connected to the bracket and protrudes from the bracket.

18. An automation system, comprising:
a chassis, comprising:
a main body;
a bracket, configured to slide relative to the main body;
a handle, rotatably disposed on the bracket, wherein the handle comprises a hook;
a locking mechanism, disposed on the main body, wherein the locking mechanism is switchable between a locked state and an unlocked state, the hook is configured to engage the locking mechanism, and the locking mechanism comprises a rotating rod pivotally connected to the main body; and
a gripped member, connected to the bracket; and
a robotic apparatus, comprising a gripper, wherein the gripper is configured to grasp the gripped member to move the bracket.

19. The automation system as claimed in claim 18, wherein the locking mechanism is switchable between the locked state and the unlocked state by rotating the rotating rod, the rotating rod comprises a latch portion, and when the locking mechanism is in the locked state, the hook engages the latch portion, the locking mechanism further comprises a lever with one end rotatably connected to a connecting end of the rotating rod, the robotic apparatus further comprises a pushing component, wherein when the pushing component pushes the lever, the lever rotates the rotating rod to switch the locking mechanism from the locked state to the unlocked state.

20. The automation system as claimed in claim 19, wherein the latch portion is located between the connecting end and a pivot portion of the rotating rod, and the rotating rod is pivotally connected to the main body via the pivot portion.
